(19) United States
(12) Patent Application Publication
(10) Pub. No.: US 2024/0215297 A1
(43) Pub. Date: Jun. 27, 2024

(54) LIGHT EMITTING DEVICE

(71) Applicants: LG Display Co., Ltd., Seoul (KR); KOREA ADVANCED INSTITUTE OF SCIENCE AND TECHNOLOGY, Daejeon (KR)

(72) Inventors: Kyung-Cheol CHOI, Daejeon (KR); Kwang-Hwan JI, Paju-si (KR); Hark-Jin KIM, Paju-si (KR); So-Yeong JEONG, Daejeon (KR)

(73) Assignees: LG Display Co., Ltd., Seoul (KR); KOREA ADVANCED INSTITUTE OF SCIENCE AND TECHNOLOGY, Daejeon (KR)

(21) Appl. No.: 18/516,391

(22) Filed: Nov. 21, 2023

(30) Foreign Application Priority Data
Dec. 19, 2022 (KR) 10-2022-0178100

(51) Int. Cl. H10K 50/844; H10K 50/115; H10K 85/10

(52) U.S. Cl. CPC H10K 50/844; H10K 50/115; H10K 85/151; H10K 59/873

(57) ABSTRACT

A light emitting device is described, which has a first encapsulation film enclosing an outside and a top surface of a light emitting diode. The first encapsulation film comprises an organic thin film of a fluorine-based polymer and an inorganic material infiltrated into a void of the fluorine-based polymer and linked chemically to the fluorine-based polymer. Optionally, a second encapsulation film can be disposed between a substrate and the light emitting diode. The encapsulation film provides a moisture barrier, while being flexible. Since the encapsulation film provides improved barrier properties to moisture and the like, the light emitting device can maintain good current density, luminous efficiency and luminance. The light emitting device can be a display device, a lighting device, a touch screen, etc.

### CROSS-REFERENCE TO RELATED APPLICATIONS

This application claims priority, under 35 U.S.C. § 119(a), to Korean Patent Application No. 10-2022-0178100, filed in the Republic of Korea on Dec. 19, 2022, the entire contents of which are hereby expressly incorporated by reference into the present application.

### BACKGROUND

### Technical Field

The present disclosure relates to a light emitting device, and more particularly, a light emitting device having beneficial moisture barrier property and flexibility.

### Description of the Related Art

Flat panel display devices including an organic light emitting diode (OLED) are increasingly being used in various applications, and have various advantages over a liquid crystal display device (LCD). For instance, the OLED can be formed as a thin organic film and the electrode configurations can implement unidirectional or bidirectional images. Also, the OLED can be formed even on a flexible transparent substrate, e.g., such as a plastic substrate, so that a flexible or a foldable display device can easily be provided using the OLED.

In addition, the OLED can be driven at a lower voltage and the OLED has advantageously high color purity compared to an LCD.

However, there remains a need to develop OLEDs and devices thereof that have improved luminous efficiency and luminous lifespan. Since fluorescent materials use only singlet excitons in the luminous process, there can be an issue with low luminous efficiency.

Meanwhile, phosphorescent materials can show a high luminous efficiency since they use triplet exciton as well as singlet excitons in the luminous process. But, examples of such phosphorescent material include metal complexes, which can have a luminous lifespan that is too short for commercial use.

Particularly the OLED can be vulnerable to external moisture and oxygen. As such, there remains a need to develop a light emitting device that has improved flexibility and that can shield efficiently foreign substances such as external moisture and oxygen.

### SUMMARY OF THE DISCLOSURE

Embodiments of the present disclosure are directed to a light emitting device that substantially obviates one or more of the problems due to the limitations and disadvantages of the related art.

An object of the present disclosure is to provide a light emitting device that has improved luminous efficiency and luminous lifespan.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides a light emitting device that comprises a substrate; a light emitting diode on the substrate; and a first encapsulation film enclosing an outside and a top surface of the light emitting diode, wherein the first encapsulation film comprises a first organic thin film of a first fluorine-based polymer and a first inorganic material infiltrating into a void of the first fluorine-based polymer and linked chemically to the first fluorine-based polymer.

In one embodiment, the first fluorine-based polymer can be selected from polyvinyl fluoride (PVF), polyvinylidene fluoride (PVDF), polytetrafluoroethylene (PTFE), polychlorotrifluoroethylene (PCTFE), perfluoroalkoxy (PFA) polymer, fluorinated ethylene (FEP) polymer, polyethylene tetrafluoro ethylene (ETFE), polyethylenechlorotrifluoroethylene (CCTFE), perfluoroelastomer (FFKM/FFPM), vinylidene fluoride-based copolymer fluoroelastomer (FPM/FKM), tetrafluoroethylene-propylene-based copolymer fluoroelastomer (FEPM), perfluoropolyether (PFPE), perfluorosulfonic acid (PFSA), perfluoropolyoextane, poly-1,1,2,4,4,5,5,6,7,7-decafluoro3-oxa-1,6-heptadiene)-perfluorotrialkylamine copolymer, combinations thereof and/or copolymers thereof.

The first fluorine-based polymer can have a surface energy in a range between about 10 mN/m and about 30 mN/m.

The first fluorine-based polymer can have a weight average molecular weight (Mw) in a range between about 150,000 and about 300,000.

The first inorganic material can be obtained from an inorganic precursor selected trimethyl aluminum (TMA), an aluminum oxide, aluminum borohydride trimethylamine (Alpis-3), dimethylsilane (DMAH), dimethylethylamine: alane (DMEAA), (ethyldimethylamine)trihydroaluminum), tetramethylsilane (4MS), bis(tert-butylamino)silane (BTBAS), bis(ethylmethylamino)silane (D2S2), diisopropylaminosilane (DIPAS), dimethyldimethoxysilane (DMDMOS), bis(dimethylsilyl)silylamine (DTDH-3H2), 1,3-diisopropyl-2,4-dimethylcylcodisilazane (CSN-2), tetrakis(dimethylamido)titanium(IV) (TDMAT), titanium tetrachloride (TiCl₄), tris(dimethylamido)zirconium cyclopentadienide (A2HP7), (cyclopentadienylxmethylcyclopentadienyl) (zirconium Bis(ethoxide), Cp(Me)CpZr(OEt)₂), tetrakis(ethylmethylamido)zirconium (TEMAZr), (hexamethyldisilazane)Tris(pyrrolidine)Hafnium ((HMDS)Hf(Py)₃), hafnium(IV) tert-butoxide (HTTB)), tetrakis(ethylmethylamido)Hafnium (TEMAHf) and/or combinations thereof.

The first inorganic material can be linked to a fluorine atom of the first fluorine-based polymer in the first encapsulation film.

For example, the first inorganic material (e.g., metal atom) can be linked to a fluorine atom of the first fluorine-based polymer through an oxygen atom in the first encapsulation film.

Optionally, the light emitting device can further comprise a second encapsulation film disposed between the substrate and the light emitting diode.

The second encapsulation film can comprise a second organic thin film of a second fluorine-based polymer and a second inorganic material infiltrating into a void of the second fluorine-based polymer and linked chemically to the second fluorine-based polymer.

The light emitting diode can comprise an organic light emitting diode and/or inorganic light emitting diode such as a quantum dot light emitting diode.

In one or more embodiments, a first encapsulation film of hybrid or composite of the organic material and the inorganic material covers or surrounds the top or upper surface and outer surface of outside of the light emitting diode, and optionally, a second encapsulation film is disposed between the substrate and the light emitting diode.

The inorganic material of the encapsulation film infiltrates a void of the organic material and chemically linked firmly to the organic material. The encapsulation film of the composite or hybrid materials of the organic material and the inorganic material can utilize advantages of the organic material and the inorganic material, and can secure beneficial moisture barrier or shielding properties. It is possible to secure equivalent luminous efficiency and luminous lifespan compared to a light emitting device where no encapsulation film is applied with improving the shielding properties.

In addition, since the encapsulation film is very flexible, the encapsulation film can be applied to a flexible light emitting device. Accordingly, it is possible to implement a light emitting device that has improved moisture shielding performance, secure equivalent luminous properties and flexible properties.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic cross-sectional view of a light emitting device in accordance with one embodiment of the present disclosure.

FIG. 2 illustrates schematically a fabrication process of an organic-inorganic hybrid encapsulation filum applied into a light emitting device of the present disclosure.

FIG. 3 illustrates a cross-sectional view of a light emitting diode with a normal structure in accordance with one embodiment of the present disclosure.

FIG. 4 illustrates a cross-sectional view of a light emitting diode with an inverted structure in accordance with another embodiment of the present disclosure.

FIG. 5 illustrates an image showing an example of an analysis result of an organic-inorganic hybrid encapsulation film prepared in an Example of the present disclosure with transmission electron microscopy (TEM) and energy dispersive X-ray spectroscopy (EDS).

FIG. 6 illustrates a graph showing an example of a measurement result of an organic-inorganic hybrid encapsulation film prepared in an Example of the present disclosure with secondary ion mass spectroscopy.

FIG. 7 illustrates an image showing an example of an analysis result of an organic-inorganic hybrid encapsulation film prepared in another Example of the present disclosure with TEM and EDS.

FIG. 8 illustrates a graph showing an example of a measurement result of water vapor transmission rate (WVTR) and flexibility for an organic-inorganic hybrid encapsulation film prepared in an Example of the present disclosure.

FIG. 9 illustrates a graph showing an example of an measurement result of WVTR for an organic-inorganic encapsulation film prepared in Examples of the present disclosure and an aluminum oxide single thin film.

FIGS. 10 and 11 illustrate graphs showing an example of X-ray photoelectron spectroscopy (XPS) analysis results for an organic-inorganic hybrid encapsulation film prepared in an Example of the present disclosure.

FIGS. 12 to 15 illustrate graphs showing an example of luminous properties of current density, luminance, current efficiency and power efficiency by voltages for an organic light emitting diode in another Example of the present disclosure and Comparative Example.

FIGS. 16 to 19 illustrate graphs showing an example of luminous properties of current density, luminance, current efficiency and power efficiency by voltages for an organic light emitting diode in another Example of the present disclosure and Comparative Examples.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. In the following description, when a detailed description of well-known functions or configurations related to this document is determined to unnecessarily cloud a gist of the inventive concept, the detailed description thereof will be or can be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations are selected only for convenience of writing the specification and can be thus different from those used in actual products. Further, all the components of each light emitting diode (LED) and each light emitting device (e.g., display device, illumination device, etc.) using the LED according to all embodiments of the present disclosure are operatively coupled and configured.

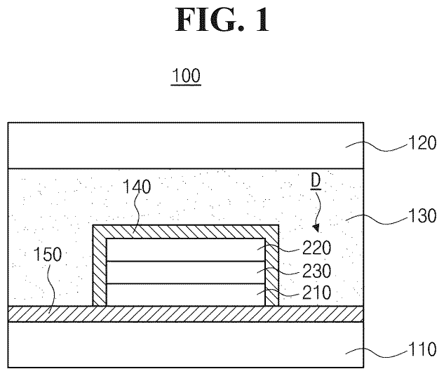

The present disclosure relates to a light emitting device where an encapsulation film of an inorganic-organic hybrid or composite thin film with beneficial moisture penetration suppression effect and flexibility are applied. FIG. 1 illustrates a schematic cross-sectional view of a light emitting display device as an example of a light emitting device.

As illustrated in FIG. 1, a light emitting device 100 comprises a substrate 110, an encapsulation film or second substrate 120 facing the substrate 110 and a light emitting diode (LED) D disposed between the substrate 110 and the encapsulation film 120. The light emitting device 100 comprises a first encapsulation film 140 that covers or surrounds a top or upper surface and an outer surface or outside of the LED D, and optionally, a second encapsulation film 150 disposed between the substrate 110 and the LED D.

The substrate 110 can include, but is not limited to, glass, thin flexible material and/or polymer plastics. For example, the flexible material of the substrate 110 can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

The LED D is disposed on the substrate 110. The LED D can comprise a first electrode 210, a second electrode 220 facing the first electrode 210 and an emissive layer 230 disposed between the first electrode 210 and the second electrode 220. For example, the LED D can comprise, but is not limited to, an organic light emitting diode (OLED) and an inorganic light emitting diode such as a quantum-dot and/or quantum-rod light emitting diode (QLED).

An adhesive layer 130 can be disposed on the LED D. The adhesive layer 130 can prevent primarily external moisture from being penetrated into the LED D. For example, the adhesive layer 130 can comprise optically clear resin (OCR). As an example, the adhesive layer 130 can comprise, but is not limited to, an acryl-based resin, a meth acryl-based resin, an epoxy-based resin, a urethane-based resin, combinations thereof and/or copolymers thereof.

The encapsulation film 120 can be disposed on the adhesive layer 130 to further prevent the moisture from being penetrated into the LED D. The encapsulation film 120 can be made of or comprise a transparent material or a semi-transparent material. For example, the encapsulation film 120 comprise, but is not limited to, glass, plastics such as polyimide, metal foil and the like.

In another embodiment, the encapsulation film 120 can have, but is not limited to, a stacking structure of a first inorganic insulating layer, an organic insulating layer, and a second inorganic insulating layer.

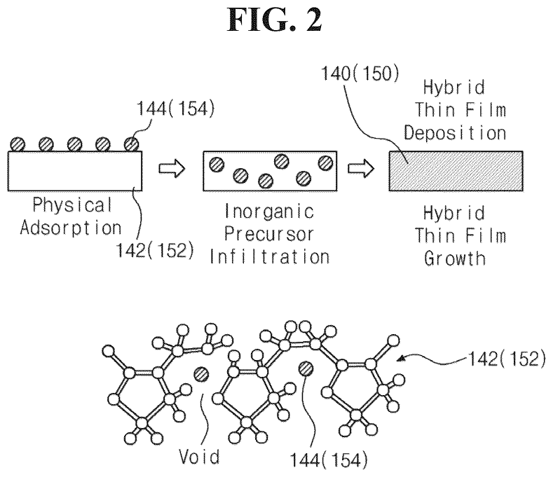

The first encapsulation film 140 and the second encapsulation film 150 will be described in more detail with referring to FIG. 2. As illustrated in FIG. 2, the first encapsulation film 140 and the second encapsulation film 150 can comprise respectively a thin film of a first organic material 142 and a second organic material 152, respectively, and a first inorganic material 144 and a second organic material 154 infiltrate into the thin film and linked chemically to the first organic material 142 and the second organic material 152, respectively. For instance, the first encapsulation film 140 can comprise the thin film of the first organic material 142 and the first inorganic material 144, whereas the second encapsulation film 150 can comprise the thin film of the second organic material 152 and the second inorganic material 154.

The thin film of the first organic material 142 and the second organic material 152 can be prepared by a solution process of coating a dispersion solution including the first organic material 142 or the second organic material 152 and evaporating a solvent within the dispersion solution. As an example, the substrate on which the first organic material 142 or the second organic material 152 can be, but is not limited to, the substrate 110 and/or the second electrode 220. For example, a solution process such as a spin coating, a drop coating, a deep coating, a spray coating, a roll coating, a flow coating, a casting process, a screen printing process and/or an ink-jet printing process can be applied to form the thin film with the first organic material 142 or the second organic material 152.

The dispersion solution can comprise a solvent that can disperse the first organic material 142 or the second organic material 152 to coat the first organic material 142 or the second organic material 152 on the substrate. As described below, each of the first organic material 142 and the second organic material 152 can be independently a fluorine-based polymer. For example, the solvent for dispersing the first organic material 142 or the second organic material 152 can include, but is not limited to, a perfluorinated organic solvent.

For example, the fluorine-based solvent for dispersing the first organic material 142 or the second organic material 142 can be selected from, but is not limited to, the group consisting of methylnonafluorobutyl ether, methylnonafluoroisobutyl ether, ethylnonafluorobutyl ether, ethylnonafluoroisobutyl ether, 1,1,1,2,3,3-hexafluoro-4-(1,1,2,3,3,3-hexafluropropoxy)-penthane, perfluorotripentylamine, perfluorotri-n-butylamine, perfluoro-n-dibutylmethylamine and/or combinations thereof.

For example, commercially available fluorine-based solvent comprise a HFE series fluorine-based solvent such as HEE-7100 (mixture of methylnonafluorobutyl ether and methylnonafluoroisobutyl ether), HFE-7200 (mixture of ethylnonafluorobutyl ether and ethylnonafluoroisobutyl ether), HFE-7300, HFE-7500, HFE-7600 (1,1,1,2,3,3-hexafluoro-4-(1,1,2,3,3,3-hexafluropropxy)-penthane); a FC series perfluorine-based solvent such as FC-40 (mixture of perfluorotri-n-butylamine and perfluoro-n-dibutylmethylamine), FC-43, FC-70 (perfluorotripentylamine), FC-72 (perfluorohexane), FC-75 (perfluoro-(2-butyl-tetrahydrofuran), FC-770, FC3283, FC-3284; and combinations thereof.

A thermal treatment or baking process can be performed to the dispersion solution including the first organic material 142 or the second organic material 152 coated on the substrate so that the solvent among the dispersion solution for forming a first organic thin film or a second organic thin film is evaporated to prepare the first organic thin film or the second organic thin film. Proper heat is applied to the dispersion solution to evaporate the solvent, for example, the heat treatment can be performed at a temperature between about 100° C. and about 250° C. for about 10 seconds to about 1000 seconds, but is not limited thereto.

Each of the first organic material 142 and the second organic material 152 of the fluorine-based polymer and the solvent for dispersing the corresponding first organic material 142 or the second organic material 152 in the dispersion solution can be mixed, but is not limited to, a weight ratio between about 10:90 and about 90:10, about 20:80 and about 80:20, or about 30:70 and about 70:30. In one embodiment, the organic thin film of each of the first organic material 142 and the second organic material 152 can have a thickness, but is not limited to, from about 1 nm to about 1000 nm, for example, from about 1 nm to about 100 nm.

In one embodiment, the dispersion solution can further comprise a curing agent and/or a crosslinking agent to expedite a crosslinking of the first organic material 142 or the second organic material 152. Any curing agent and/or crosslinking agent that can expedite the crosslinking the fluorine-based polymer. As an example, the curing agent and/or the crosslinking agent can comprise, but is not limited to, 1,6-bis(trichlorosilyl)hexane. For example, the curing agent and/or crosslinking agent can be added into the dispersion solution including the first organic material 142 and/or the second organic material 152 with a volumetric ratio in a range between about 0.1 volumetric % and about 5 volumetric %, for example, about 0.1 volumetric % and about 0.5 volumetric %.

Each of the first inorganic material 144 and the second inorganic material 154 can be obtained from any inorganic precursor that can be used in an atomic layer deposition (ALD) process. When an inorganic thin film is deposited on an organic thin film, a functional group attached at a surface of the organic thin film can be reacted with the inorganic precursor, an interface between the organic material and the inorganic material is formed in the surface of the organic thin film, only the inorganic thin film is grown, and a double-layered structure where the organic material and the inorganic material is separated is formed.

When a material with a low surface energy, for example, the first organic material 142 or the second organic material 152 of the fluorine-based polymer less reactive as the first organic thin film or the second organic thin film material, the reaction between the first organic material 142 or the second organic material 154 and the first inorganic material 144 or the second inorganic material 154 at the surface of the first organic thin film or the second organic thin film is not occurred in case of depositing the first inorganic precursor 144 or the second inorganic precursor 154 on the surface of the first organic thin film or the second organic thin film. Rather, each of the first inorganic precursor 144 and the second inorganic precursor 154 infiltrates to a void, for example, a free volume of the first organic thin film or the second organic thin film including the first organic material 142 or the second organic material.

Each of the first inorganic precursor 144 and the second inorganic precursor 154 infiltrated to a void of the first organic thin film or the second organic thin film including the first organic material 142 or the second organic material 154 is chemically linked firmly to each of the first organic material 142 and the second organic material 152, respectively. As such, each of the first encapsulation film 140 and the second encapsulation film 150 of an organic-inorganic hybrid thin film where each of the first inorganic material 144 and the second inorganic material 154 is chemically linked to each of the first organic material 142 and the second organic material 152, respectively, in each of the first organic thin film and the second organic thin film.

The method for depositing each of the first inorganic precursor 144 and the second inorganic precursor 154 to the surface of the first organic thin film or the second organic thin film including each of the first organic material 142 and the second organic material 152 is not limited to a particular method, and, for example, an atomic layer deposition (ALD) process can be used. For example, in the atomic layer deposition process, the injection time of each precursor gas is 0.05 seconds to 0.5 seconds, and the purge process of supplying the purge gas for 2 seconds to 20 seconds between injections of the precursor gas as one cycle can be made of approximately 200 to 300 cycles, but is not limited thereto.

The first organic material 142 and the second organic material 152 into which the first inorganic material 144 and the second inorganic material 154 are respectively infiltrated to a void thereof can be a first fluorine-based polymer and a second fluorine-based polymer, respectively. For example, each of the first organic material 142 and the second organic material 152 can be selected from, but is not limited to, the group consisting of polyvinyl fluoride (PVF), polyvinylidene fluoride (PVDF), polytetrafluoroethylene (PTFE), polychlorotrifluoroethylene (PCTFE), perfluoroalkoxy (PFA) polymer, fluorinated ethylene (FEP) polymer, polyethylene tetrafluoro ethylene (ETFE), polyethylenechlorotrifluoroethylene (CCTFE), perfluoroelastomer (FFKM/FFPM), vinylidene fluoride-based copolymer fluoroelastomer (FPM/FKM), tetrafluoroethylene-propylene-based copolymer fluoroelastomer (FEPM), perfluoropolyether (PFPE), perfluorosulfonic acid (PFSA), perfluoropolyoextane, poly-1,1,2,4,4,5,5,6,7,7-decafluoro3-oxa-1,6-heptadiene)-perfluorotrialkylamine copolymer, combinations thereof and/or copolymers thereof.

In one embodiment, commercially available fluorine-based polymer can be used as the first organic material 142 and/or the second organic material 152. As an example, CYTOP® of Asahi Glass can be used as the fluorine-based polymer. In another embodiment, the fluorine-based polymer can have a weight average molecular weight (Mw) in a range between about 150,000 and about 300,000. For example, CTL-809, CTL-190AE, CTL-809M and/or CTL107MK of weight average molecular weight (Mw) between about 150,000 and about 200,000, and/or CTX-809A, CTX-109AE and/or CTX809SP2 of weight average molecular weight (Mw) between about 250,000 and about 300,000.

In one embodiment, each of the first organic material 142 and the second organic material 152 of the fluorine-based polymer can have a surface energy in a range between about 10 mN/m and about 30 mN/m, for example, between about 15 mN/m and about 20 mN/m. In this case, each of the first inorganic precursor 144 and the second inorganic precursor 154 may not react with the first organic material 142 or the second organic material 152 at the surface of the first organic thin film or the second organic thin film.

Any inorganic precursor can be used to form the first inorganic material 144 or the second inorganic material 154 that infiltrates into the first organic thin film or the second organic thin film through the void within the first organic thin film or the second organic thin film including the first organic material or the second organic material and form firm chemical bonds with each of the first organic material 142 and the second organic material, respectively.

As an example, each of the first inorganic material 144 and the second inorganic material 154 can be independently obtained from an inorganic precursor selected from, but is not limited to, the group consisting of trimethyl aluminum (TMA), an aluminum oxide, aluminum borohydride trimethylamine (Alpis-3), dimethylsilane (DMAH), dimethylethylamine: alane (DMEAA), (ethyldimethylamine)trihydroaluminum), tetramethylsilane (4MS), bis(tert-butylamino)silane (BTBAS), bis(ethylmethylamino)silane (D2S2), diisopropylaminosilane (DIPAS), dimethyldimethoxysilane (DMDMOS), bis(dimethylsilyl)silylamine (DTDH-3H2), 1,3-diisopropyl-2,4-dimethylcylcodisilazane (CSN-2), tetrakis(dimethylamido)titanium(IV) (TDMAT), titanium tetrachloride (TiCl₄), tris(dimethylamido)zirconium cyclopentadienide (A2HP7), (cyclopentadienyl)(methylcyclopentadienyl) (zirconium Bis(ethoxide), Cp(Me)CpZr(OEt)₂), tetrakis(ethylmethylamido)zirconium (TEMAZr), (hexamethyldisilazane)Tris(pyrrolidine)Hafnium ((HMDS)Hf(Py)₃), hafnium(IV) tert-butoxide (HTTB)), tetrakis(ethylmethylamido)Hafnium (TEMAHf) and/or combinations thereof.

As an example, each of the first inorganic material 144 and the second inorganic material 154 can be chemically linked to a fluorine atom of the first organic material 142 or the second organic material 154 of the fluorine-based polymer. In one example, when each of the first inorganic material 144 and the second inorganic material 154 includes a metal component, a metal atom constituting each of the first inorganic material 144 and the second inorganic material 154 can be linked to a fluorine atom through an oxygen atom constituting each of the first organic material 142 and the second organic material 152 of the fluorine-based polymer in each of the first encapsulation film 140 and the second encapsulation film 150, respectively.

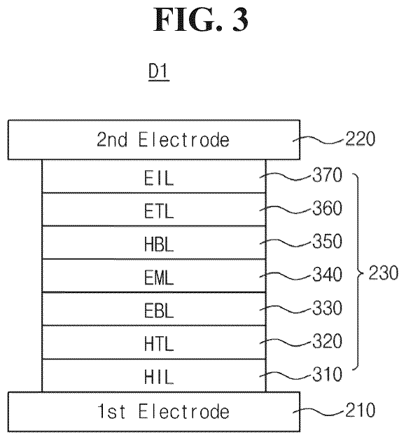

The light emitting diode D will be described in more detail. FIG. 3 illustrates a cross-sectional view of a light emitting diode with a normal structure in accordance with one embodiment of the present disclosure.

As illustrated in FIG. 3, a light emitting diode D1 comprises a first electrode 210, a second electrode 220 facing the first electrode 210 and an emissive layer 230 disposed between the first electrode 210 and the second electrode 220.

The emissive layer 230 comprises an emitting material layer (EML) 340. The emissive layer 230 can comprise at least one of a hole transport layer (HTL) 320 disposed between the first electrode 210 and the EML 340 and an electron transport layer (ETL) 360 disposed between the EML 340 and the second electrode 220. The emissive layer 230 can further comprise at least one of a hole injection layer (HIL) 310 disposed between the first electrode 210 and the HTL 320 and an electron injection layer (EIL) 370 disposed between the ETL 360 and the second electrode 220. Alternatively or additionally, the emissive layer 230 can further comprise at least one of an electron blocking layer (EBL) 330 disposed between the HTL 320 and the EML 340 and a hole blocking layer (HBL) 350 disposed between the EML 340 and the ETL 360.

In one embodiment, the first electrode 210 can be anode such as hole injection electrode. The first electrode 210 can be disposed on the substrate 110 (FIG. 1) of glass or the polymer. As an example, the first electrode 210 can include an undoped or doped metal oxide such as indium-tin-oxide (ITO), indium-zinc-oxide (IZO), indium-tin-zinc-oxide (ITZO), indium-copper-oxide (ICO), SnO₂, In₂O₃, cadmium:zinc oxide (Cd:ZnO), fluorine:tin oxide (F:SnO₂), indium:tin oxide (In:SnO₂), gallium:tin oxide (Ga:SnO₂), and aluminum:zinc oxide (Al:ZnO, AZO). Alternatively or additionally, the first electrode 210 can comprise a metal material or a non-metal material including nickel (Ni), platinum (Pt), gold (Au), silver (Ag), iridium (Ir) and/or carbon nanotube (CNT).

The second electrode 220 can be a cathode such as electron injection electrode. As an example, the second electrode 220 can comprise, but is not limited to, Ca, Ba, Ca/Al, LiF/Ca, LiF/Al, BaF₂/Al, CaCO₃/Al, BaF₂/Ca/Al, Al, Mg, Au:Mg and/or Ag:Mg, for example, each of the first electrode 210 and the second electrode 220 can have a thickness, but is not limited to, from about 10 nm to about 300 nm.

The HIL 310 facilitates hole injections from the first electrode 210 to the EML 340. The HIL 310 can include an organic material and/or an inorganic material. In one embodiment, the organic material of the HIL 310 can comprise, but is not limited to, 4,4′,4″-tris(3-methylphenylamino)triphenylamine (MTDATA), 4,4′,4″-Tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB; NPD), N,N′-bis{4-[bis(3-methylphenyl)amino]phenyl}-N,N′-diphenyl-4,4′-biphenyldiamine (DNTPD), 1,4,5,8,9,11-hexaazatriphenylenehexacarbonitrile (dipyrazino[2,3-f:2′3′-h]quinoxaline-2,3,6,7,10,11-hexacarbonitrile; HAT-CN), 2,3,5,6-tetrafluoro-7,7,8,8-tetracyano-quinodimethane (F4-TCNQ), 1,3,4,5,7,8-hexafluoro-tetracyano-naphthoquinodimethane (F6-TCNNQ), 1,3,5-tris[4-(diphenylamino)phenyl]benzene (TDAPB), poly(3,4-ethylenedioxythiophene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), di-[4-(N,N-di-p-tolyl-amino)-phenyl]cyclohexane (TAPC), N4,N4,N4′,N4′-tetra[(1,1′-biphenyl)-4-yl]-(1,1′-biphenyl)-4,4′-diamine (BPBPA), and/or combinations thereof.

In another embodiment, the HIL 310 can include a hole transporting material described below doped with the above hole injecting material (e.g., HAT-CN, F4-TCNA and/or F6-TCNNQ). In this case, the contents of the hole injecting material in the HIL 310 can be, but is not limited to, about 2 wt % to about 15 wt %.

In another embodiment, the HIL 310 can comprise, but is not limited to, an inorganic material such as MgF₂, CaF₂, WO₃, MoO₃ and/or combinations thereof. In certain embodiments, the HIL 310 can be omitted according to the property of the LED D1.

The HTL 320 transport holes from the first electrode 210 to the EML 340. The HTL 320 can comprise an organic material and/or an inorganic material. The organic material of the HTL 320 can comprise, but is not limited to, NPB(NPD), N,N′-bis(3-methylphenyl)-N,N′-bis(phenyl)-spiro (spiro-TPD), N,N′-diphenyl-N,N′-bis(3-methylphenyl)-1,1′-biphenyl-4,4′-diamine (TPD), DNTPD, poly[N,N′-bis(4-butylpnehyl)-N,N′-bis(phenyl)-benzidine] (Poly-TPD), 4,4′-bis(N-carbazolyl)-1,1′-biphenyl (CBP), poly[(9,9-dioctylfluorenyl-2,7-diyl)-co-(4,4′-(N-(4-sec-butylphenyl)diphenylamine))] (TFB), TAPC, 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-biphenyl]-4-yl)-9,9-dimethyl-N-(4-(9-phenl-9H-carbazol-3-vl)phenyl)-9H-fluoren-2-amine) and/or combinations thereof.

The inorganic material of the HTL 320 can comprise, but is not limited to, a metal oxide such as NiO, MoO₃, Bi₂O₃ and/or P-type ZnO; a non-oxide such as CuSCN, Mo₂S and P-type GaN and/or combinations thereof.

Each of the HIL 310 and the HTL 320 can be laminated by any vacuum deposition process such as vacuum vapor deposition and sputtering, or by any solution process such as spin coating, drop coating, dip coating, spray coating, roll coating, flow coating, casting, screen printing and inkjet printing, or combinations thereof. For example, each of the HIL 310 and the HTL 320 can have a thickness, but is not limited to, from about 1 nm to about 200 nm, for example, from about 1 nm to about 100 nm.

The EML 340 can include inorganic luminescent particles or organic luminescent material. As an example, the EML 340 can include inorganic luminescent particles such as quantum dots (QDs) or quantum rods (QRs).

Here, QDs or QRs are inorganic luminescent particles that emit light as unstable stated excitons drop from conduction band to valence band. Those inorganic luminescent particles have very large extinction coefficient, high quantum yield among inorganic particles and generates strong fluorescence. In addition, these inorganic luminescent particles show different luminescence wavelengths as its sizes, it is possible to emit light within the entire visible light spectra so as to implement various colors by adjusting sizes of these inorganic luminescent particles. When these inorganic luminescent particles such as QDs and/or QRs are used as a luminous material in the EML 340, it is possible to enhance color purity in individual pixel region and realize white (W) light consisting of red (R), green (G) and blue (B) light having high color purity.

In one embodiment, QDs or QRs can have a single-layered structure. In another embodiment, QDs or QRs can have a multiple-layered heterologous structure, i.e., core/shell structure. In this case, each of the core and the shell can have single layer or multiple layers, respectively.

The reactivity of precursors, which can be synthesized to the core and/or the shell, injection rates of the precursors into a reaction vessel, reaction temperature and kinds of ligands bonded to an outer surface of those inorganic luminescent particles such as QDs or QRs can have affect upon the growth rates and crystal structures of those inorganic luminescent particles. As a result, it is possible to emit lights of various luminescent wavelength ranges, as the energy level bandgap of those inorganic luminescent particles are adjusted.

As an example, the QDs or QRs can have a heterologous structure including a core provided at a central portion thereof and configured to emit light and a shell covering a surface of the core to protect the core, and a ligand component for dispersing the QDs or QRs in a solvent can cover a surface of the shell. For example, the QDs or QRs can have a type-I core/shell structure in which electrons and holes move towards the core and are recombined in the core, and as a result, energy is emitted as light, as a structure in which the energy bandgap of a component constituting the core is covered by the energy bandgap of the shell.

In a case where the QDs or QRs have a type-I core/shell structure, the core is a portion in which light emission substantially occurs, and the luminescence wavelength of the QDs or QRs is determined according to the size of core. To achieve a quantum confinement effect, it is necessary for the core to have a size smaller than an exciton Bohr radius according to each material, and have an optical bandgap in the corresponding size.

Meanwhile, the shell of the QDs or QRs promotes a quantum confinement effect of the core and determines the stability of the QDs or QRs. Unlike internal atoms, atoms that appear on surfaces of colloidal QDs or QRs having a single structure have lone pair electrons that do not participate in chemical bonding. The energy level of these surface atoms is between a conduction band edge and a valence band edge of the QDs or QRs, and thus charges can be trapped, resulting in formation of surface defects. Luminous efficiency of the QDs or QRs can be reduced due to a non-radiative recombination process of excitons which results from the surface defects, and the trapped charges react with external oxygen and a compound and thus can cause modification of a chemical composition of the QDs or QRs, or electric/optical properties of the QDs or QRs can be permanently lost.

Thus, in one example embodiment, the QDs or QRs can have a heterologous structure including a core and a shell. In order for the shell to be efficiently formed on a surface of the core, a lattice constant of a material constituting the shell should be similar to that of a material constituting the core. By covering the surface of the core with the shell, oxidation of the core is prevented and thus chemical stability of the QDs or QRs can be enhanced, loss of excitons due to surface trapping at the surface of the core can be minimized, and energy loss due to molecular vibration can be prevented, resulting in enhancement of quantum efficiency.

The QDs or QRs can be semiconductor nanocrystals or metal oxide particles having a quantum confinement effect. For example, the QDs or QRs can include Group II-IV, III-V, IV-VI, or I-III-VI compound semiconductor nanocrystals. More particularly, cores and/or shells constituting the QDs or QRs can be Group II-VI compound semiconductor nanocrystals such as CdS, CdSe, CdTe, ZnS, ZnSe, ZnTe, HgS, HgTe, and/or a combination thereof; Group III-V compound semiconductor nanocrystals such as GaP, GaAs, GaSb, InP, InAs, InSb, and/or a combination thereof; Group IV-VI compound semiconductor nanocrystals such as PbS, PbSe, PbTe, and/or a combination thereof: Group I-III-VI compound semiconductor nanocrystals such as AgGaS₂, AgGaSe₂, AgGaTe₂, CuInS₂, CulnSe₂, CuGaS₂, CuGaSe₂, and/or a combination thereof; metal oxide nanoparticles such as ZnO, TiO₂, and/or a combination thereof; or core-shell structured nanocrystals such as CdSe/ZnSe, CdSe/ZnS, CdS/ZnSe, CdS/ZnS, ZnSe/ZnS, InP/ZnS, ZnO/MgO, and/or a combination thereof. Semiconductor nanoparticles can be undoped or doped with a rare earth element such as europium (Eu), erbium (Er), terbium (Tb), thulium (Tm), or dysprosium (Dy), or a combination thereof, or can be doped with a transition metal element such as manganese (Mn), copper (Cu), silver (Ag), or aluminum (Al), or a combination thereof.

For example, cores constituting the QDs or QRs can be selected from the group consisting of ZnSe, ZnTe, CdSe, CdTe, InP, ZnCdS, CuₓIn₁₋ₓS, CuₓIn₁₋ₓSe, AgₓIn₁₋ₓS, and a combination thereof. In addition, shells constituting the QDs or QRs can be selected from the group consisting of ZnS, GaP, CdS, ZnSe, CdS/ZnS, ZnSe/ZnS, ZnS/ZnSe/CdSe, GaP/ZnS, CdS/CdZnS/ZnS, ZnS/CdSZnS, CdxZn₁₋ₓS, and/or a combination thereof.

Meanwhile, the QDs can be alloy QDs (e.g., CdSₓSe₁₋ₓ, CdSeₓTe₁₋ₓ, and ZnₓCd₁₋ₓSe) such as homogeneous alloy QDs or gradient alloy QDs.

When the EML 340 is formed of inorganic luminescent particles such as QDs or QRs, a solution including QDs or QRs in a solvent is applied to the HTL 320, and then the solvent is evaporated, thereby forming the EML 340. The EML 340 can be formed using one solution process selected from spin coating, drop coating, dip coating, spray coating, roll coating, flow coating, casting, screen printing, and inkjet printing, or a combination thereof.

In one embodiment, the EML 340 can include QDs or QRs, which are inorganic luminescent nanoparticles having photoluminescence (PL) emission properties at 440 nm, 530 nm, and 620 nm, and thus the manufacture of a white light-emitting diode is enabled. Optionally, the EML 150 can include QDs or QRs, which are luminescent nanoparticles having any one of a red color, a green color, and a blue color, and can be formed such that the EML 340 individually emits light of any one color.

In other embodiments, the EML 340 can be formed of an organic luminescent material. The organic luminescent material of the EML 340 is not particularly limited as long as it is a generally used organic luminescent material. For example, the EML 340 can be formed of an organic luminescent material that emits red light, green light, and/or blue light, and can include a fluorescent material or a phosphorescent material. In addition, the organic luminescent material of the EML 340 can include a host and an emitter (a dopant). The emitter can comprise at least one of a phosphorescent material, a fluorescent material and a delayed fluorescent material.

When the organic luminescent material comprises a host-dopant system, the dopant can be doped in an amount of about 1 wt % to about 50 wt %, preferably about 1 wt % to about 30 wt %, with respect to the weight of the host, but the present disclosure is not limited to the above example.

An organic host used in the EML 340 is not particularly limited as long as it is a commonly used material. For example, the organic host used in the EML 340 can comprise a P-type host and/or an N-type host. The P-type host can comprise, but is not limited to, a carbazole-based compound, an aryl amine-based compound, a hetero aryl amine-based compound and a spirofluorene-based compound. The N-type host can comprise, but is not limited to, an azine-based compound, a quinoxaline-based compound, a quinazoline-based compound.

In one embodiment, the organic host can comprise, but tris(8-hydroxyquinoline)aluminum (Alq₃), 9-(3-(9H-carbazol-9-yl)phenyl)-9H-carbazole-3-carbonitrile(mCP-CN), CBP, 3,3′-bis(N-carbazolyl)-1,1′-biphenyl (mCBP), 1,3-bis(carbazol-9-yl)benzene (mCP), bis[2-(diphenylphosphino)phenyl]ether oxide (DPEPO), 2,8-bis(diphenylphosphoryl)dibenzothiophene (PPT), 1,3,5-Tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′,7,7′-tetrakis(carbazole-9-yl)-9,9-spirofluorene (Spiro-CBP), 3,6-bis(carbazole-9-yl)-9-(2-ethyl-hexyl)-9H-carbazole (TCzl), 9,10-di(naphthalene-2-yl)anthracene (ADN), 3-tert-butyl-9,10-di(naphtha-2-yl)anthracene (TBADN), 2-methyl-9,10-bis(naphthalene-2-yl)anthracene (MADN), 1,3,5-tris(N-phenylbenzimidazole-2-yl)benzene (TPBi), distyrylarylene (DSA), 1,3,5-tris(carbazol-9-yl)benzene (TCP), bis(10-hydroxybenzo[h]quinolinato)beryllium (Bebq2), 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1), 9,9′-(5-(Triphenylsilyl)-1,3-phenylene)bis(9H-carbazole)(SimCP) and/orcombinations thereof.

When the EML 340 emits a red color light, a red emitter of the EML 340 can comprise at least one of a red phosphorescent material, a red fluorescent material and a red delayed fluorescent material. As an example, the red emitter can compries, but is not limited to, bis[2-(4,6-dimethyl)phenylquinoline)](2,2,6,6-tetramethylheptane-3,5-dionate)iridium(III), Bis[2-(4-n-hexylphenyl)quinoline](acetylacetonate)iridium(III) (Hex-Ir(phq)₂(acac)), tris[2-(4-n-hexylphenyl)quinoline]iridium(III) (Hex-Ir(phq)₃), tris[2-phenyl-4-methylquinoline]iridium(III) (Ir(Mphq)₃), bis(2-phenylquinoline)(2,2,6,6-tetramethylheptene-3,5-dionate)iridium(III) (Ir(dpm)PQ₂), tris(1-phenylisoquinoline)iridium(III) (Ir(piq)₃), bis(phenylisoquinoline)(2,2,6,6-tetramethylheptene-3,5-dionate)iridium(III) (Ir(dpm)(piq)₂), bis(1-phenylisoquinoline)(acetylacetonate)iridium(III) (Ir(piq)₂(acac)), bis[(4-n-hexylphenyl)isoquinoline](acetylacetonate)iridium(III) (Hex-Ir(piq)₂(acac)), tris[2-(4-n-hexylphenyl)quinoline]iridium(III) (Hex-Ir(piq)₃), tris(2-(3-methylphenyl)-7-methyl-quinolato)iridium (Ir(dmpq)₃), bis[2-(2-methylphenyl)-7-methylquinoline](acetylacetonate)iridium(III) (Ir(dmpq)₂(acac)), bis[2-(3,5-dimethylphenyl)-4-methylquinoline](acetylacetonate)iridium(III) (Ir(mphmq)₂(acac)), tris(dibenzovlmethane)mono(1,10-phenanthroline)europium(III) (Eu(dbm):(phen)) and/or combinations thereof.

When the EML 340 emits a green color light, a green emitter of the EML 340 can comprise at least one of a green phosphorescent material, a green fluorescent material and a green delayed fluorescent material. As an example, the green emitter can comprise, but is not limited to, [bis(2-phenylpyridine)](pyridyl-2-benzofuro[2,3-b]pyridine)iridium, tris[2-phenylpyridine]iridium(III) (Ir(ppy)), fac-tris(2-phenylpyridine)iridium(III) (fac-Ir(ppy)₃), bis(2-phenylpyridine)(acetylacetonate)iridium(III) (Ir(ppy)₂(acac)), tris[2-(p-tolyl)pyridine]iridium(III) (Ir(mppy)₃), bis(2-(naphthalene-2-yl)pyridine)(acetylacetonate)iridium(III) (Ir(npy)₂acac), tris(2-phenyl-3-methyl-pyridine)iridium (Ir(3mppy)₃), fac-tris(2-(3-p-xylyl)phenyl)pyridine iridium(III) (TEG) and/or combinations thereof.

When the EML 340 emits a blue color light, a blue emitter of the EML 340 can comprise at least one of a blue phosphorescent material, a blue fluorescent material and a blue delayed fluorescent material. As an example, the blue emitter can comprise, but is not limited to, perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-tetra-tetr-butylperylene (TBPe), bis((2-hydroxylphenyl)-pyridine)beryllium (Bepp₂), 9-(9-phenylcarbazol-3-yl)-10-(naphthalen-1-yl)anthracene (PCAN), mer-tris(1-phenyl-3-methylimidazolin-2-ylidene-C,C(2))′iridium(III) (mer-Ir(pmi)₃), fac-tris(1,3-diphenyl-benzimidazolin-2-ylidene-C,C(2))′iridium(III) (fac-Ir(dpbic)₃), bis(3,4,5-trifluoro-2-(2-pyridyl)phenyl-(2-carboxypyridyl))iridium(III) (Ir(tfpd)₂pic), tris(2-(4,6-difluorophenyl)pyridine)iridium(III) (Ir(Fppy)₃), bis[2-(4,6-difluorophenyl)pyridinato-C²,N](picolinato)iridium(III) (FIrpic), DABNA-1, DABNA-2, t-DABNA, v-DABNA and/or combinations thereof.

When the EML 340 includes the organic luminescent material, the EML 340 can be formed using one selected from a vacuum deposition process including vacuum vapor deposition and sputtering, and a solution process such as spin coating, drop coating, dip coating, spray coating, roll coating, flow coating, casting, screen printing, and inkjet printing; or a combination of these processes.

The ETL 360 and the ELL 370 can be laminated sequentially between the EML 340 and the second electrode 220. An electron transporting material included in the ETL 360 has high electron mobility so as to provide electrons stably with the EML 340 by fast electron transportation.

In one embodiment, the ETL 360 can comprise an organic material and/or an inorganic material. The organic electron transporting material in the ETL 360 can include at least one of an oxadiazole-based compound, a triazole-based compound, a phenanthroline-based compound, a benzoxazole-based compound, a benzothiazole-based compound, a benzimidazole-based compound, and a triazine-based compound.

For example, the organic electron transporting material in the ETL 360 can include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 2,2′, 2″-(1,3,5-benzenetriyl)-tris(1-phenyl-1-H-benzimidazole) (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenanthroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] dibromide (PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN) and/or combinations thereof.

In another embodiment, the inorganic electron transporting material of the ETL 360 can comprise metal or non-metal oxide, a semiconductor particle, a nitride and/or combinations thereof. The metal or non-metal oxide can comprise, but is not limited to, titanium dioxide (TiO₂), zinc oxide (ZnO), zinc magnesium oxide (ZnMgO), zirconium oxide (ZrO), tin oxide (SnO₂), tungsten oxide (WO₃), tantalum oxide (Ta₂O₃), hafnium oxide (HfM₃), aluminum oxide (Al₂O₃), zirconium silicon oxide (ZrSiO₄), barium titanium oxide (BaTiO₃), and barium zirconium oxide (BaZrO₃).

The semiconductor particles can comprise, but is not limited to, CdS, ZnSe, and ZnS. In one embodiment, the ETL 360 can comprise the metal or the non-metal oxide since the oxides has beneficial electron injection property and therefore can improve the luminous efficiency of the LED D1.

The EIL 370 facilitates injection of electrons from the second electrode 220 into the EML 340. For example, electron injecting material of the EIL 370 can comprise aluminum (Al), cadmium (Cd), cesium (Cs), copper (Cu), gallium (Ga), germanium (Ge), indium (In), or lithium (Li) with fluorine or binding such a metal to fluorine; and/or a metal oxide such as titanium dioxide (TiO₂), zinc oxide (ZnO), zirconium oxide (ZrO), tin oxide (SnO₂), tungsten oxide (WO₃), or tantalum oxide (Ta₂O₃) that is undoped or doped with Al, magnesium (Mg), In, Li, Ga, Cd, Cs, Cu, or the like. Alternatively, electron injecting material in the EIL 370 can comprise, but is not limited to, an organometallic compound such as Liq, lithium benzoate, sodium stearate, and the like.

In an alternative embodiment, the ETL 360 and the EIL 370 can have a single layered structure. In this case, the above electron transporting material and/or the electron injecting material can be mixed with each other. As an example, the ETL/EIL can include two or more different electron transporting materials. For example, two electron transporting materials in the ETL/EIL are admixed with a weight ratio of about 3:7 to about 7:3, but is not limited thereto.

Each of the ETL 360 and the EIL 370 can be formed using one solution process selected from spin coating, drop coating, dip coating, spray coating, roll coating, flow coating, casting, screen printing, and inkjet printing; or a combination thereof. For example, each of the ETL 360 and the EIL 370 can have a thickness, but is not limited to, from about 0.5 nm to about 200 nm, for example, from about 1 nm to about 100 nm.

When holes are transferred to the second electrode 220 via the EML 340, or electrons are transferred to the first electrode 210 via the EML 340, the LED D1 can have a short lifespan and a reduced luminous efficiency. In order to prevent or address those phenomena, the LED D1 can further include at least one exciton blocking layer disposed adjacently to the EML 340.

For example, the LED D1 can further include the EBL 330 between the HTL 320 and the EML 340 so as to control and prevent electron transportation. As an example, electron blocking material in the EBL 330 can include, but is not limited to, TCTA, N-(biphenyl-4-yl)-9,9-dimethyl-N-(4-(9-phenyl-9H-carbazol-3-yl)phenyl)-9H-fluoren-2-amine, TAPC, MTDATA, 1,3-Bis(carbazol-9-yl)benzene (mCP), 3,3-Di(9H-carbazol-9-yl)biphenyl (mCBP), CuPc, DNTPD, TDABP, DCDPA, 2,8-bis(9-phenyl-9H-carbazol-3-yl)dibenzo[b,d]thiophene and/or combinations thereof.

In addition, the LED D1 can further include the HBL 350 between the EML 340 and the ETL 360 so that holes cannot be transferred from the EML 340 to the ETL 360. In one embodiment, hole blocking material in the HBL 350 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, a hole blocking material in the HBL 350 can include a material having a relatively low HOMO energy level compared to the luminescent materials in EML 340. The HBL 370 can include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof. In certain embodiments, each of the EBL 330 and/or the HBL 370 can be omitted.

As described above, the light emitting device 100 (FIG. 1) comprise the first encapsulation film 140 that covers or surrounds the top surface and the outside of the LED D1, and optionally, the second encapsulation film 150 disposed between the first electrode 210 and the substrate 110. As the external moisture shielding performance improves, the degradation of the luminous materials, carrier injecting materials and carrier transporting materials can be prevented. The first and second encapsulation films 140 and 150 with beneficial flexibility enables the light emitting device 100 to be flexible and to implement stable luminous efficiency and luminous lifespan.

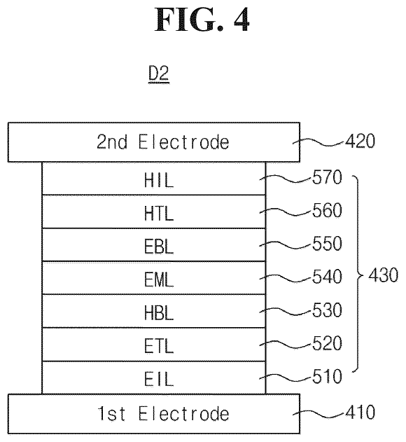

The LED D1 with a normal structure where a hole transfer layer such as the HIL 310 and the HTL 320 is disposed between the first electrode 210 with a relatively low work function value and the EML 340 and an electron transfer layer such as the ETL 360 and the EIL 370 is disposed between the second electron 220 with a relatively high work function value and the EML 340 is described in FIG. 3. The light emitting diode that can have an inverted structure not the normal structure will be described. FIG. 4 illustrates a cross-sectional view of a light emitting diode with an inverted structure in accordance with another embodiment of the present disclosure.

As illustrated in FIG. 4, a light emitting diode D2 with the inverted structure comprises a first electrode 410, a second electrode 420 facing the first electrode 410 and an emissive layer 430 disposed between the first electrode 410 and the second electrode 420.

The emissive layer 430 comprises an emitting material layer (EML) 540. The emissive layer 430 can comprise at least one of an electron transport layer (ETL) 520 disposed between the first electrode 410 and the EML 520 and a hole transport layer (HTL) 560 disposed between the EML 540 and the second electrode 420. The emissive layer 430 can further comprise at least one of an electron injection layer (EIL) 510 disposed between the first electrode 410 and the ETL 520 and a hole injection layer (HIL) 570 disposed between the second electrode 420 and the HTL 560. The emissive layer 430 can further comprise at least one of a hole blocking layer (HBL) 530 disposed between the ETL 520 and the EML 540 and an electron blocking layer (EBL) 550 disposed between the EML 540 and the HTL 560.

The first electrode 410 can be a cathode such as an electron injection electrode. As an example, the first electrode 410 can include, but is not limited to, Ca, Ba, Ca/Al, LIF/Ca, LiF/Al, BaF₂/Al, CsF/Al, CaCO₃/Al, BaF?/Ca/Al, Al, Mg, Au: Mg and/or Ag: Mg. The second electrode 420 can be an anode such as a hole injection electrode. As an example, the second electrode 420 can include, but is not limited to, undoped or doped metal oxide such as ITO, IZO, ITZO, ICO, SnO₂, In₂O₃, Cd: ZnO, F: SnO₂, In: SnO₂, Ga: SnO₂ and/or AZO; Ni, Pt, Au, Ag, Ir, carbon nanotube and/or combinations thereof.

In the second embodiment, the first electrode 410 of the cathode is disposed adjacently to the substrate 110 (FIG. 1), and the second electrode 420 of the anode can be disposed facing to the first electrode 410. The EIL 510, the ETL 520 and the HBL 530 are disposed sequentially between the first electrode 410 and the EML 540. The EBL 550, the HTL 560 and the HIL 570 are disposed sequentially between the EML 540 and the second electrode 420. The materials and/or the components of the emissive layer 530 can be identical to the corresponding materials with referring to FIG. 3 except the relative locations of the carrier injection layer such as the EIL 510 and the HIL 570, the carrier transport layer such as the ETL 520 and the HTL 560 and the carrier blocking layer such as the HBL 530 and the EBL 550.

In this embodiment, the light emitting device 100 (FIG. 1) comprises a first encapsulation film 140 (FIG. 1) that covers or surrounds the top surface and the outside of the LED D2, and optionally, the second encapsulation film 150 (FIG. 1) disposed between the first electrode 510 and the substrate 110 (FIG. 1). As the external moisture shielding performance improves, the degradation of the luminous materials, carrier injecting materials and carrier transporting materials can be prevented. The first and second encapsulation films 140 and 150 with beneficial flexibility enables the light emitting device 100 to be flexible and to implement stable luminous efficiency and luminous lifespan.

### Preparation Example 1: Preparation of Hybrid Encapsulation Film

Dispersion solution mixing CYTOP® undiluted of a fluorine-based polymer having the following repeating structure with a fluorine-based solvent with a volumetric ratio of 3:20 was coated on a silicon substrate by using spin coating method with 1000 rpm for 60 seconds, then the fluorine-based polymer was cured by heat treatment at 100° C. The cured organic thin film was put into a chamber at 70° C., then atomic layer deposition (ALD) cycle was performed by spraying trimethyl aluminum of inorganic precursor for 0.2 second, purging nitrogen gas for 10 seconds, purging H₂O gas 0.2 second, and purging nitrogen gas for 10 second. By operating 200-300 cycles of ALD, organic-inorganic hybrid or composite encapsulation film was prepared.

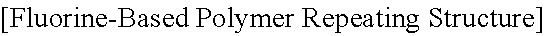

### Preparation Example 2: Preparation of Hybrid Encapsulation Film

A hybrid encapsulation film was prepared using the same procedure and the same material as Preparation Example 1, except that 1,6-bis(trichlorosilyl) hexane curing agent of a volumetric ratio of 0.17% based upon the dispersion solution was added to the dispersion solution with the fluorine-based polymer and the fluorine-based solvent.

### Experimental Example 1: Analysis of Components of Hybrid Encapsulation Film

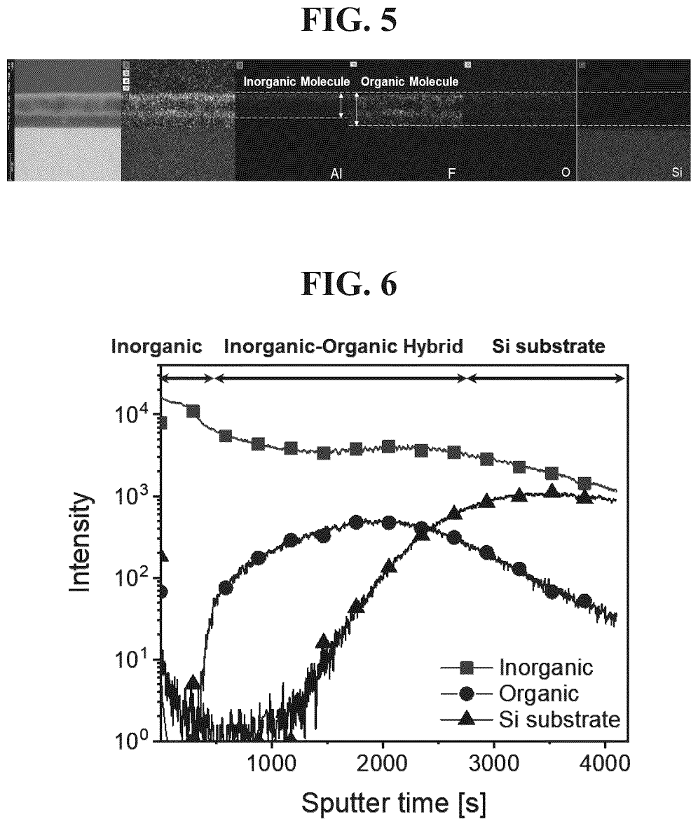

The components of the organic-inorganic hybrid encapsulation film prepared in Preparation Example 1 were analyzed by TEM and EDS. Analysis results are illustrated in FIG. 5. In addition, the components of the hybrid encapsulation film were analyzed by secondary ion mass spectrometry. Analysis result is illustrated in FIG. 6. The inorganic material was aluminum-related elements and the inorganic material was fluorine-related elements. It was confirmed that the inorganic and organic elements coexisted at the same depth, and the organic and inorganic materials coexisted.

### Experimental Example 2: Analysis of Components of Hybrid Encapsulation Film

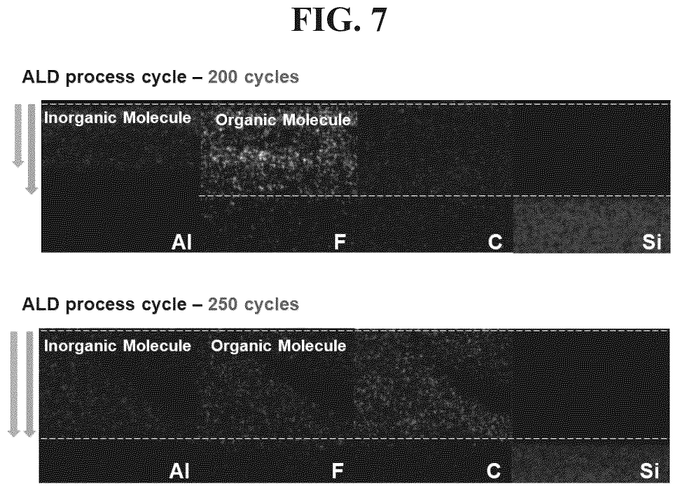

Components of the organic-inorganic hybrid encapsulation film prepared by the ALD process cycle in the organic-inorganic hybrid encapsulation film prepared in Preparation Example 1 were analyzed in the same manner as in Experimental Example 1 using TEM and EDS. The analysis results are illustrated in FIG. 7. It was confirmed that the inorganic material infiltrated more deeply into the organic thin film as the ALD process cycle increased.

### Experimental Example 3: Evaluation of Moisture Permeation Rate and Flexibility Hybrid Encapsulation Film

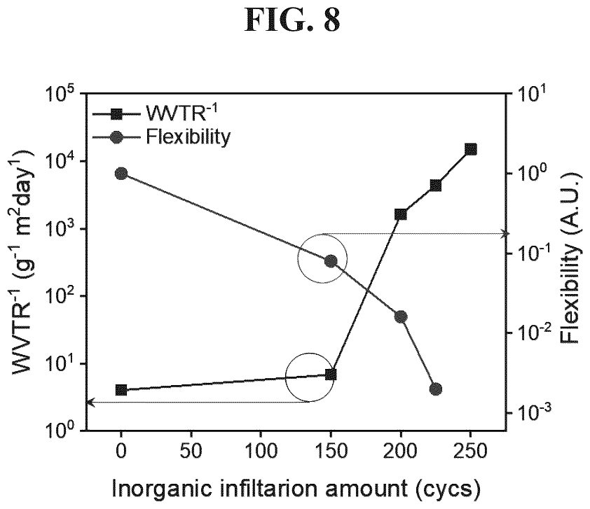

Moisture permeation rate of water vapor transmission rate (WVTR) and flexibility of the organic-inorganic hybrid encapsulation film prepared in Preparation Example 1 by the ALD process cycle were evaluated. The water vapor transmission rate was evaluated by wrapping the organic-inorganic hybrid encapsulation film prepared in Preparation Example 1 with a Ca thin film sensitive to moisture and measuring the electrical conductivity of Ca. Flexibility was evaluated by the WVTR ration before and after bending (WVTR before bending/WVTR after bending) by repeating 100 times as a bending strain of 2%. The evaluation results are illustrated in FIG. 8. As the ALD process cycle increased, water permeation was effectively blocked, and as the ALD process cycle decreased, there was little change in WVTR, confirming that the hybrid encapsulation film had high flexibility.

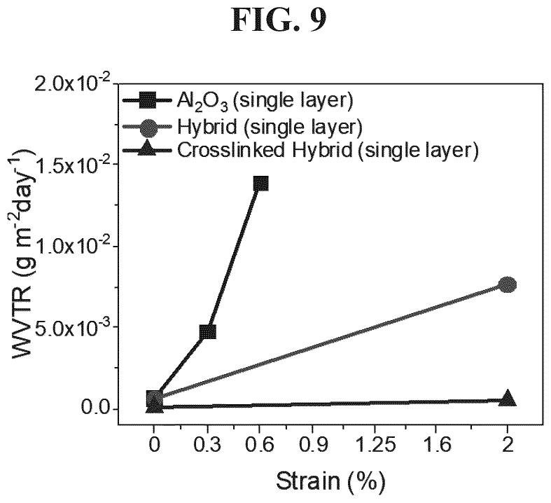

In addition, the WVTR was measured in the same manner as above for the aluminum oxide thin film used as the encapsulating material, the organic-inorganic hybrid thin film in Preparation Example 1 and the crosslinked organic-inorganic hybrid thin film in Preparation Example 2. The measurement results are illustrated in FIG. 9. Compared to the aluminum oxide thin film, both the organic-inorganic hybrid encapsulation films prepared in Preparation Example 1 and Preparation Example 2 effectively suppressed moisture permeation, and in particular, moisture permeation in the organic-inorganic composite encapsulation film prepared in Preparation Example 2 did not substantially occur after bending 1000 times by a strain of 2%.

### Experimental Example 4: XPS Analysis of Hybrid Encapsulation Film

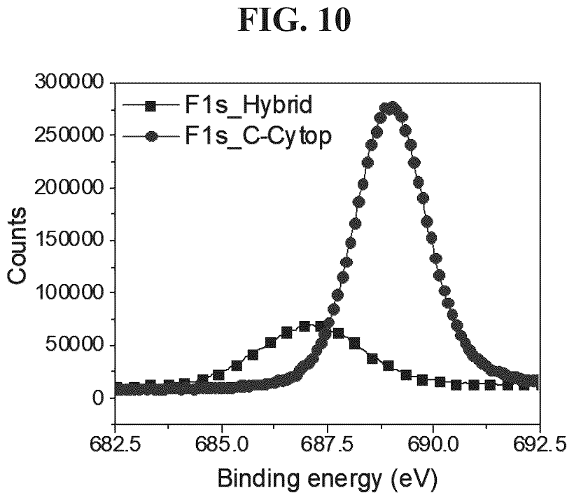

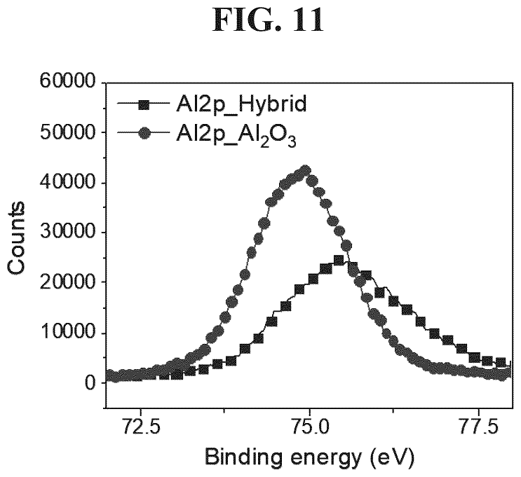

An XPS analysis for the organic-inorganic hybrid encapsulation film prepared in Preparation Example 1 was performed. The XPS analysis result for the fluorine atom is illustrated in FIG. 10 and the XPS analysis result for the aluminum atom is illustrated in FIG. 11. When a boding energy of the fluorine atom included in the organic material was shifted from 689.0 eV to 687.2 eV by −1.8 eV. This result indicates a metal fluoride bond in a carbon-fluorine linkage. As Al₂O₃ as an inorganic material was infiltrated into the organic material, it was expected that an aluminum-fluorine bond are formed in the hybrid encapsulation film. The boding energy of the aluminum atom in the inorganic material was shifted from 74.9 eV to 75.5 eV by +0.6 eV. This result indicates an AlOCFₓ bond.

### Example 1 (Ex. 1): Fabrication of OLED with Normal Structure

An organic light emitting diode with a normal structure where a top encapsulation film (first encapsulation film) were disposed over a top surface and outside of the organic light emitting diode. The first encapsulation film was prepared as in Preparation Example 2. The organic light emitting diode was fabricated as the following order:

Anode (Ag, 30 nm); hole injection layer (MoO₃, 5 nm); hole transport layer (NPB, 62 nm); red emitting material layer (Bebq2 (92 wt %), Ir(piq)₃ (8 wt %), 70 nm); electron injection layer (Liq, 1 nm); and cathode (Al, 100 nm);

### Comparative Example 1 (Ref. 1): Fabrication of OLED with Normal Structure

An organic light emitting diode with a normal structure was fabricated using the same material and process as Example 1 except that any of a bottom encapsulation film and a top encapsulation film was not disposed.

### Experimental Example 5: Measurement of Luminous Properties of OLED

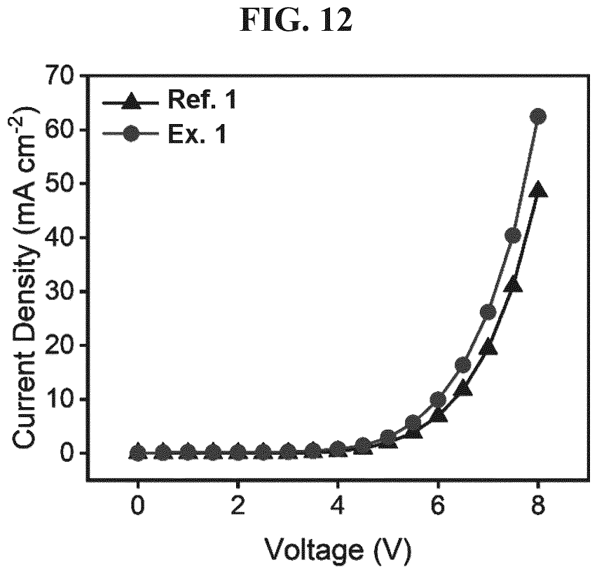

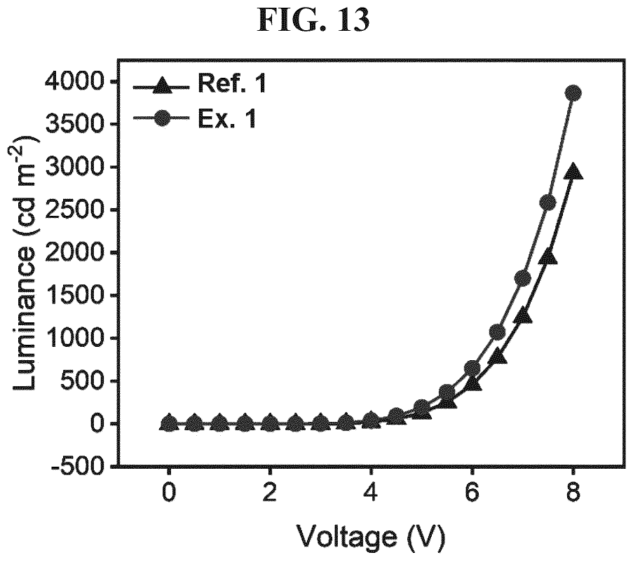

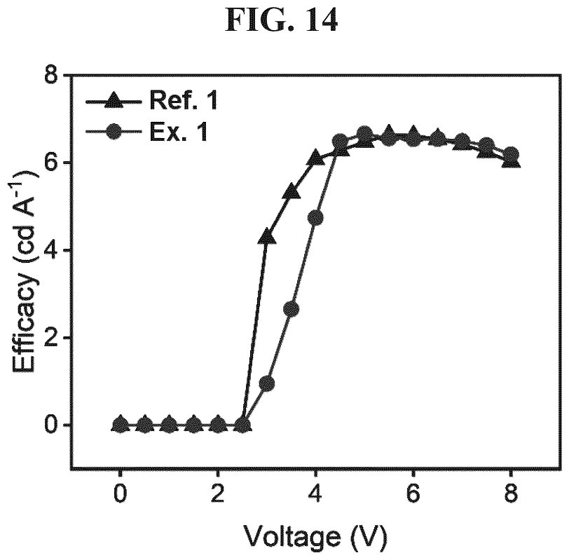

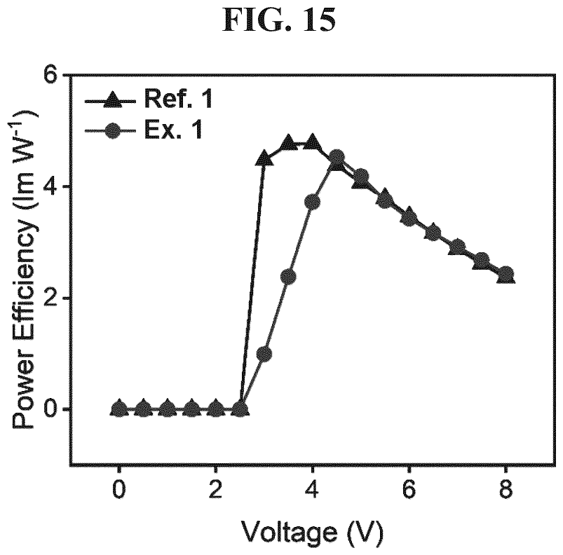

The luminous properties for each of the OLEDs, fabricated in Example 1 and Comparative Example 1, were measured. Each of the OLEDs were connected to an external power source and then luminous properties for all the OLEDs were evaluated using a constant current source (KEITHLEY) and a photometer CS2000 at room temperature. In particular, the driving voltage (V), luminance (cd/m²), current efficiency (cd/A) and power efficiency (lm/W) for the OLEDs were measured at a current density of 10 mA/cm². The measurement results are illustrated in the following Table 1 and FIGS. 12 to 15.

TABLE 1
Luminous Properties of OLED

| Sample | V | cd/m² | cd/A | lm/W |
|---|---|---|---|---|
| Ref. 1 | 6.3 | 655 | 6.55 | 3.3 |
| Ex. 1 | 6 | 653 | 6.53 | 3.4 |

### Example 2 (Ex. 2): Fabrication of OLED with Inverted Structure

An organic light emitting diode with an inverted structure where a bottom encapsulation film (second encapsulation film) on a flexible substrate and top encapsulation film (first encapsulation film) disposed a top surface and outside of the organic light emitting diode was fabricated. The first encapsulation film and the second encapsulation film were prepared as in Preparation Example 2, respectively. The organic light emitting diode was fabricated as the following order:

Anode (Al, 100 nm); electron injection layer (Liq, 1 nm); emitting material layer (Alq₃, 50 nm); hole transport layer (NPB, 50 nm), hole injection layer (MoO₃, 5 nm); and cathode (Ag, 30 nm);

### Comparative Examples 2-3 (Ref. 2-3): Fabrication of OLED with Normal Structure

An organic light emitting diode with an inverted structure was fabricated using the same material and process as Example 2 except that any of a bottom encapsulation film and a top encapsulation film were not disposed (Comparative Example 2) or only the bottom encapsulation film on the substrate was disposed (Comparative Example 3).

### Experimental Example 6: Measurement of Luminous Properties of OLED

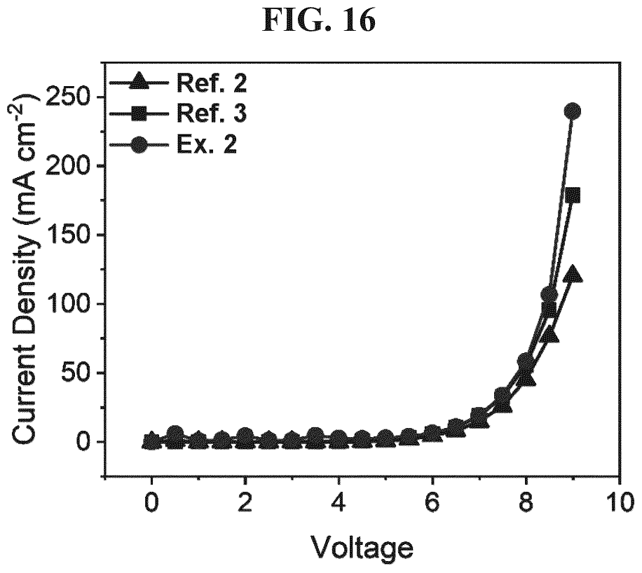

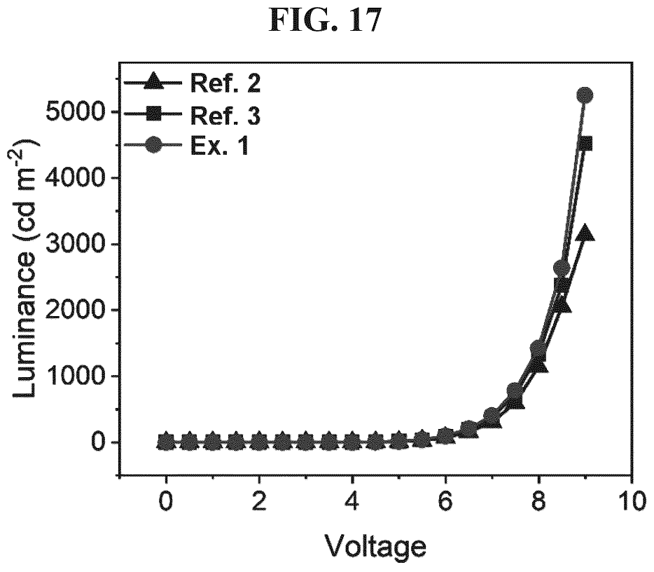

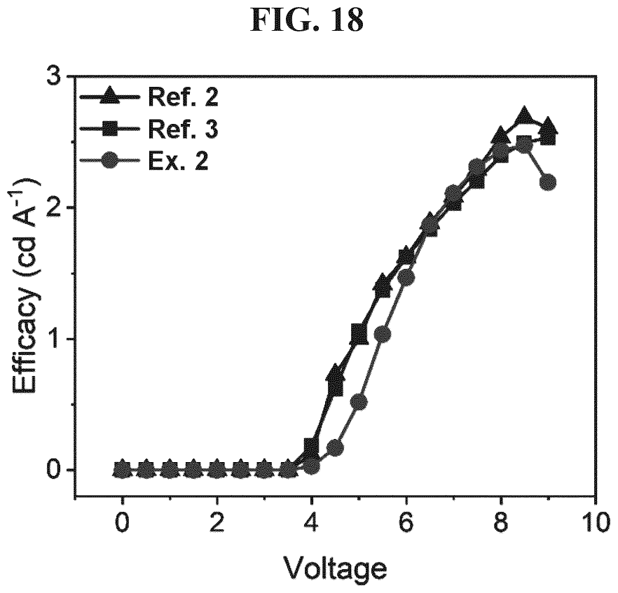

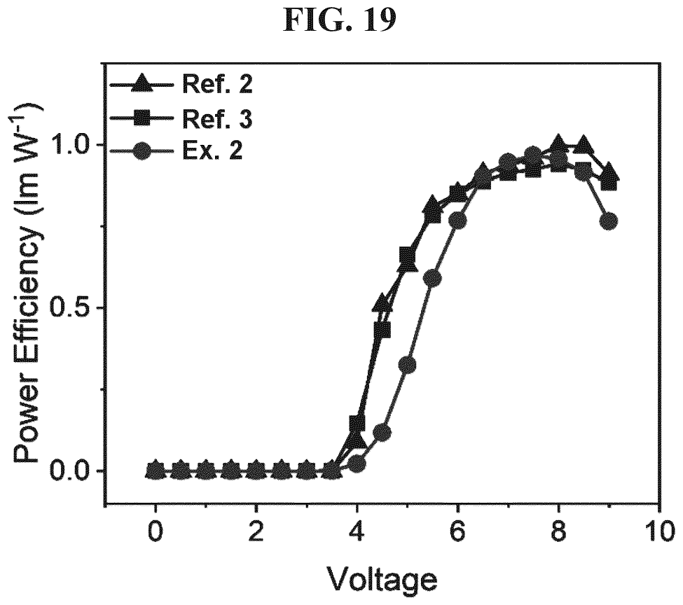

The luminous properties for each of the OLEDs, fabricated in Example 2 and Comparative Examples 2-3, were measured as Experimental Example 5. The measurement results are illustrated in the following Table 2 and FIGS. 16 to 19.

TABLE 2
Luminous Properties of OLED

| Sample | V | cd/m² | cd/A | lm/W |
|---|---|---|---|---|
| Ref. 2 | 6.6 | 200 | 2.0 | 0.91 |
| Ref. 3 | 6.4 | 190 | 1.9 | 0.86 |
| Ex. 2 | 6.3 | 190 | 1.9 | 0.88 |

As indicated in Tables 1 and 2 as well as FIGS. 12 to 19, when the bottom encapsulation film disposed between the substrate and the organic light emitting diode and/or the top encapsulation film covering the top surface and the outside of the organic light emitting diode are disposed, as in Examples 1 and 2, the driving voltage was rather decreased and the luminance, current efficiency and power efficiency can be maintained.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A light emitting device, comprising:
a light emitting diode on a substrate and having an outside surface and a top surface; and
a first encapsulation film enclosing the outside surface and the top surface of the light emitting diode,
wherein the first encapsulation film comprises a first organic thin film of a first fluorine-based polymer and a first inorganic material, and
wherein the first inorganic material is configured to infiltrate into at least one void of the first fluorine-based polymer, and is linked chemically to the first fluorine-based polymer.

2. The light emitting device of claim 1, wherein the first fluorine-based polymer is selected from polyvinyl fluoride (PVF), polyvinylidene fluoride (PVDF), polytetrafluoroethylene (PTFE), polychlorotrifluoroethylene (PCTFE), perfluoroalkoxy (PFA) polymer, fluorinated ethylene (FEP) polymer, polyethylene tetrafluoro ethylene (ETFE), polyethylenechlorotrifluoroethylene (CCTFE), perfluoroelastomer (FFKM/FFPM), vinylidene fluoride-based copolymer fluoroelastomer (FPM/FKM), tetrafluoroethylene-propylene-based copolymer fluoroelastomer (FEPM), perfluoropolyether (PFPE), perfluorosulfonic acid (PFSA), perfluoropolyoextane, poly-1,1,2,4,4,5,5,6,7,7-decafluoro3-oxa-1,6-heptadiene)-perfluorotrialkylamine copolymer, combinations thereof and/or copolymers thereof.

3. The light emitting device of claim 1, wherein the first fluorine-based polymer has a surface energy in a range between about 10 mN/m and about 30 mN/m.

4. The light emitting device of claim 1, wherein the first fluorine-based polymer has a weight average molecular weight (Mw) in a range between about 150,000 and about 300,000.

5. The light emitting device of claim 1, wherein the first inorganic material is obtained from an inorganic precursor selected from trimethyl aluminum (TMA), an aluminum oxide, aluminum borohydride trimethylamine (Alpis-3), dimethylsilane (DMAH), dimethylethylamine: alane (DMEAA), (ethyldimethylamine)trihydroaluminum), tetramethylsilane (4MS), bis(tert-butylamino)silane (BTBAS), bis(ethylmethylamino)silane (D2S2), diisopropylaminosilane (DIPAS), dimethyldimethoxysilane (DMDMOS), bis(dimethylsilyl)silylamine (DTDH-3H2), 1,3-diisopropyl-2,4-dimethylcylcodisilazane (CSN-2), tetrakis(dimethylamido)titanium(IV) (TDMAT), titanium tetrachloride (TiCl₄), tris(dimethylamido)zirconium cyclopentadienide (A2HP7), (cyclopentadienylxmethylcyclopentadienyl) (zirconium Bis(ethoxide), Cp(Me)CpZr(OEt)₂), tetrakis(ethylmethylamido)zirconiuum (TEMAZr), (hexamethyldisilazane)Tris(pyrrolidine)Hafnium ((HMDS)Hf(Py)₃), hafnium(IV) tert-butoxide (HTTB)), tetrakis(ethylmethylamido)Hafnium (TEMAHf) and/or combinations thereof.

6. The light emitting device of claim 1, wherein the first inorganic material is linked to a fluorine atom of the first fluorine-based polymer in the first encapsulation film.

7. The light emitting device of claim 1, wherein the first inorganic material is linked to a fluorine atom of the first fluorine-based polymer through an oxygen atom in the first encapsulation film.

8. The light emitting device of claim 1, further comprising:
a second encapsulation film disposed between the substrate and the light emitting diode.

9. The light emitting device of claim 8, wherein the second encapsulation film comprises a second organic thin film of a second fluorine-based polymer and a second inorganic material,
wherein the second inorganic material is configured to infiltrate into at least one void of the second fluorine-based polymer and is linked chemically to the second fluorine-based polymer.

10. The light emitting device of claim 9, wherein the second fluorine-based polymer is selected from polyvinyl fluoride (PVF), polyvinylidene fluoride (PVDF), polytetrafluoroethylene (PTFE), polychlorotrifluoroethylene (PCTFE), perfluoroalkoxy (PFA) polymer, fluorinated ethylene (FEP) polymer, polyethylene tetrafluoro ethylene (ETFE), polyethylenechlorotrifluoroethylene (CCTFE), perfluoroelastomer (FFKM/FFPM), vinylidene fluoride-based copolymer fluoroelastomer (FPM/FKM), tetrafluoroethylene-propylene-based copolymer fluoroelastomer (FEPM), perfluoropolyether (PFPE), perfluorosulfonic acid (PFSA), perfluoropolyoextane, poly-1,1,2,4,4,5,5,6,7,7-decafluoro3-oxa-1,6-heptadiene)-perfluorotrialkylamine copolymer, combinations thereof and/or copolymers thereof.

11. The light emitting device of claim 9, wherein the second fluorine-based polymer has a surface energy in a range between about 10 mN/N and about 30 mN/m.

12. The light emitting device of claim 9, wherein the second fluorine-based polymer has a weight average molecular weight (Mw) in a range between about 150,000 and about 300,000.

13. The light emitting device of claim 9, wherein the second inorganic material is obtained from an inorganic precursor selected from trimethyl aluminum (TMA), an aluminum oxide, aluminum borohydride trimethylamine (Alpis-3), dimethylsilane (DMAH), dimethylethylamine: alane (DMEAA), (ethyldimethylamine)trihydroaluminum), tetramethylsilane (4MS), bis(tert-butylamino)silane (BTBAS), bis(ethylmethylamino)silane (D2S2), diisopropylaminosilane (DIPAS), dimethyldimethoxysilane (DMDMOS), bis(dimethylsilyl)silylamine (DTDH-3H2), 1,3-diisopropyl-2,4-dimethylcylcodisilazane (CSN-2), tetrakis(dimethylamido)titanium(IV) (TDMAT), titanium tetrachloride (TiCl₄), tris(dimethylamido)zirconium cyclopentadienide (A2HP7), (cyclopentadienylxmethylcyclopentadienyl) (zirconium Bis(ethoxide), Cp(Me)CpZr(OEt)₂), tetrakis(ethylmethylamido)zirconium (TEMAZr), (hexamethyldisilazane)Tris(pyrrolidine)Hafnium ((HMDS)Hf(Py)₃), hafnium(IV) tert-butoxide (HTTB)), tetrakis(ethylmethylamido)Hafnium (TEMAHf) and/or combinations thereof.

14. The light emitting device of claim 9, wherein the second inorganic material is linked to a fluorine atom of the second fluorine-based polymer in the second encapsulation film.

15. The light emitting device of claim 9, wherein the second inorganic material is linked to a fluorine atom of the second fluorine-based polymer through an oxygen atom in the second encapsulation film.

16. The light emitting device of claim 1, wherein the light emitting diode is an organic light emitting diode.

17. The light emitting device of claim 1, wherein the light emitting diode is a quantum dot light emitting diode.

18. The light emitting device of claim 1, wherein the light emitting device is a light emitting display device configured to display images.
